(19) United States
(12) Patent Application Publication
(10) Pub. No.: US 2026/0189230 A1
(43) Pub. Date: Jul. 2, 2026

(54) DRIVING CHIP, BIDIRECTIONAL POWER APPARATUS, AND MANUFACTURING METHOD

(71) Applicant: Silergy Semiconductor Technology (Hangzhou) LTD, Hangzhou (CN)

(72) Inventors: Li Zhang, Hangzhou (CN); Qiyue Zhao, Hangzhou (CN); Xiao Wang, Hangzhou (CN); Pengxiang Bai, Hangzhou (CN)

(21) Appl. No.: 19/427,390

(22) Filed: Dec. 19, 2025

(30) Foreign Application Priority Data
Dec. 31, 2024 (CN) 202411998922.6

(51) Int. Cl. H03K 17/16; H02M 1/08; H10D 80/30; H10D 84/01; H10D 84/80

(52) U.S. Cl. CPC H03K 17/162; H02M 1/08; H10D 80/30; H10D 84/0109; H10D 84/017; H10D 84/0172; H10D 84/0186; H10D 84/0191; H10D 84/811

(57) ABSTRACT

A driving chip for driving a bidirectional power device and modulating a substrate potential of the bidirectional power device, the bidirectional power device comprising a first power end, a second power end, a control end, and a substrate potential end, can include: a driving circuit; a substrate potential modulation circuit; where the driving circuit and the substrate potential modulation circuit are formed on a same substrate; and where the substrate potential modulation circuit is configured to receive signals from the control end and from the first power end and/or the second power end, and is coupled to the substrate potential end, such that a voltage at the substrate potential end of the bidirectional power device is substantially consistent with a lowest voltage among voltages at the control end, the first power end, and the second power end.

### RELATED APPLICATIONS

This application claims the benefit of Chinese Patent Application No. 202411998922.6, filed on Dec. 31, 2024, which is incorporated herein by reference in its entirety.

### FIELD OF THE INVENTION

The present invention generally relates to the field of integrated circuit design, and more particularly to driving chips, bidirectional power apparatuses, manufacturing methods for a driving chip, and manufacturing methods for a bidirectional power apparatus.

### BACKGROUND

With increasing requirements for the size and energy efficiency of power devices, wide bandgap semiconductor Gallium Nitride (GaN) devices, due to their lower power loss and faster switching capability, have been widely applied in power conversion apparatuses. In certain applications requiring bidirectional switching, a Gallium Nitride High Electron Mobility Transistor (GaN HEMT) device can be equivalently regarded as two transistors coupled in a back-to-back series configuration.

### BRIEF DESCRIPTION OF THE DRAWINGS

FIG. 1 is a circuit diagram of an example driving chip, in accordance with embodiments of the present invention.

FIG. 2 is a circuit diagram of a first example substrate potential modulation circuit of a bidirectional power device integrated in the driving chip, in accordance with embodiments of the present invention.

FIG. 3 is a circuit diagram of a second example substrate potential modulation circuit of a bidirectional power device integrated in the driving chip, in accordance with embodiments of the present invention.

FIG. 4 is a schematic diagram of an example substrate structure of the driving chip, in accordance with embodiments of the present invention.

FIG. 5 is a schematic cross-sectional diagram of an example intermediate structure obtained after simultaneously forming a first well region and/or a second well region, and simultaneously forming a third well region and a fourth well region in the substrate, in accordance with embodiments of the present invention.

FIG. 6A is a schematic cross-sectional diagram of a first example intermediate structure obtained after simultaneously forming corresponding source/drain regions in different well regions, in accordance with embodiments of the present invention.

FIG. 6B is a schematic cross-sectional diagram of a second example intermediate structure obtained after simultaneously forming corresponding source/drain regions in different well regions, in accordance with embodiments of the present invention.

FIG. 7A is a schematic cross-sectional diagram of a first example intermediate structure obtained after forming a dielectric layer on an upper surface of the substrate, in accordance with embodiments of the present invention.

FIG. 7B is a schematic cross-sectional diagram of a second example intermediate structure obtained after forming a dielectric layer on an upper surface of the substrate, in accordance with embodiments of the present invention.

FIG. 8A is a schematic cross-sectional diagram of a first example intermediate structure obtained after respectively and simultaneously forming a first gate and/or a second gate, a third gate, and a fourth gate on an upper surface of the substrate, in accordance with embodiments of the present invention.

FIG. 8B is a schematic cross-sectional diagram of a second example intermediate structure obtained after respectively and simultaneously forming a first gate and/or a second gate, a third gate, and a fourth gate on an upper surface of the substrate, in accordance with embodiments of the present invention.

FIG. 9A is a schematic cross-sectional diagram of a first example intermediate structure obtained after respectively forming a first metal electrode, a second metal electrode, a third metal electrode, and a fourth metal electrode, in accordance with embodiments of the present invention.

FIG. 9B is a schematic cross-sectional diagram of a second example intermediate structure obtained after respectively forming a first metal electrode, a second metal electrode, a third metal electrode, and a fourth metal electrode, in accordance with embodiments of the present invention.

FIG. 10 is a schematic diagram of a first example structure obtained after fabricating a driving chip on a first substrate and simultaneously fabricating a bidirectional power device on a second substrate, in accordance with embodiments of the present invention.

FIG. 11 is a schematic diagram of a second example structure obtained after fabricating a driving chip on a first substrate and simultaneously fabricating a bidirectional power device on a second substrate, in accordance with embodiments of the present invention.

FIG. 12 is a schematic diagram of a third example structure obtained after fabricating a driving chip on a first substrate and simultaneously fabricating a bidirectional power device on a second substrate, in accordance with embodiments of the present invention.

FIG. 13 is a schematic diagram of a fourth example structure obtained after fabricating a driving chip on a first substrate and simultaneously fabricating a bidirectional power device on a second substrate, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

As compared with two Si-based transistors that are connected in series, a Bipolar Gallium Nitride High Electron Mobility Transistor (Bi-GaN HEMT) offers lower power consumption and a more compact size. However, during the switching process, if the substrate of the Bi-GaN HEMT is floating, charges can accumulate in the substrate during device switching, which adversely affects the switching performance and causes degradation of dynamic resistance. In conventional power devices, in order to avoid the impact of substrate floating on device performance and reliability, the substrate is typically maintained at the same potential as the source. Yet, in bidirectional power devices, since the source and drain switch according to the operating state of the circuit, the substrate may not be directly electrically connected to either the source or the drain. At present, most bidirectional power devices incorporate internal potential management structures to regulate the substrate potential. However, such clamping circuits may not only introduce additional parasitic capacitance, thereby affecting device efficiency, but also increase the overall cost of the bidirectional power device.

To address the above issues, certain embodiments provide a driving chip that integrates a substrate potential modulation circuit and a driving circuit of a bidirectional power device into the same chip. Without increasing the cost and parasitic parameters of the bidirectional power device itself, the structure of the potential modulation circuit can be adjusted according to actual applications, thereby better achieving control of the substrate potential. Below, particular examples are provided to describe the technical solution of particular embodiments, as well as how the technical solution addresses the above technical problems. The following examples may be combined with each other, and for the same or similar concepts or processes, detailed descriptions may be omitted in some examples.

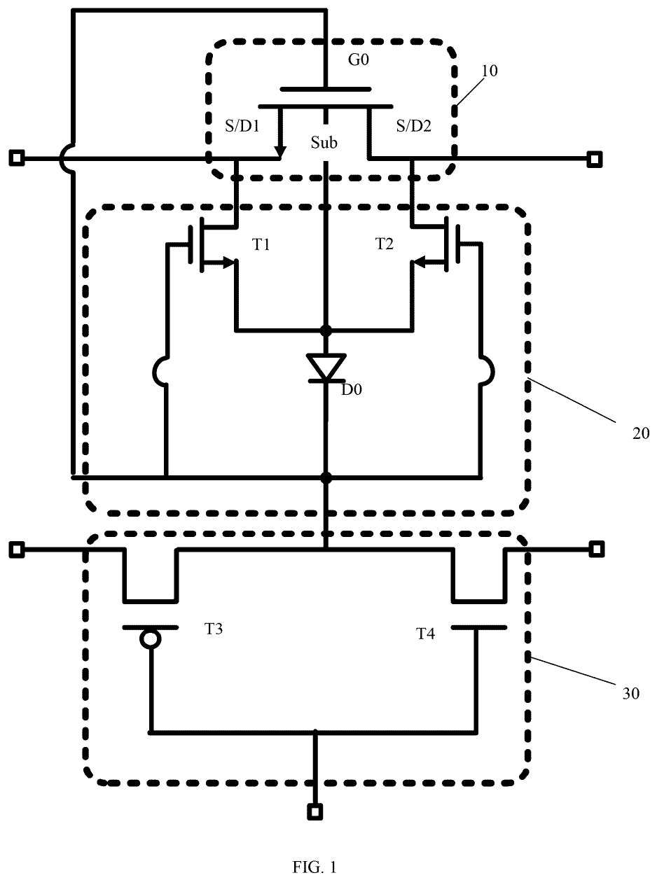

Referring now to FIG. 1, shown is an example driving chip, in accordance with embodiments of the present invention. In this particular example, the driving chip can include driving circuit 30 and substrate potential modulation circuit 20. The driving circuit may drive bidirectional power device 10, and substrate potential modulation circuit 20 can modulate a substrate potential of the bidirectional power device. The bidirectional power device is a class of power electronic devices capable of conducting current in two directions and controlling current flow. The bidirectional power device may include, e.g., bidirectional metal-oxide-semiconductor field-effect transistors (MOSFETs), bidirectional insulated gate bipolar transistors (IGBTs), or bidirectional SiC/GaN devices.

In particular embodiments, bidirectional power device 10 may be a bidirectional GaN device. Bidirectional power device 10 may also be other suitable bidirectional power devices in certain embodiments. Optionally, driving circuit 30 and substrate potential modulation circuit 20 can be formed in the same substrate, such that the potential modulation circuit can be fabricated concurrently when fabricating the driving circuit, which can reduce manufacturing steps, thereby improving production efficiency, and reduce the cost of independently fabricating the potential modulation circuit, and in turn lowers the overall manufacturing cost of the power conversion apparatus.

In some examples, as shown in FIG. 1, bidirectional power device 10 can include control end G0, power end S/D1, power end S/D2, and substrate potential end Sub. Driving circuit 30 can connect to control end G0, and may drive bidirectional power device 10. Substrate potential modulation circuit 20 can receive signals from control end G0 and from power end S/D1 and/or power end S/D2, and can connect to substrate potential end Sub, such that a voltage of substrate potential end Sub of the bidirectional power device is substantially consistent with (e.g., the same as) a lowest voltage among voltages at control end G0, power end S/D1, and power end S/D2.

Based on this, the substrate potential modulation circuit in the driving chip provided in certain embodiments can maintain the voltage at substrate potential end Sub of the bidirectional power device substantially consistent with the lowest voltage among the voltages at control end G0, power end S/D1, and power end S/D2, thereby avoiding the impact of substrate floating on the performance and reliability of the bidirectional power device. In particular embodiments, the potential modulation circuit can be integrated into the driving chip of the bidirectional power device. This may not only avoid increasing the cost and parasitic parameters of the bidirectional power device, but also allow the potential modulation circuit to be designed according to particular requirements, thereby better achieving management of the substrate potential of the bidirectional power device.

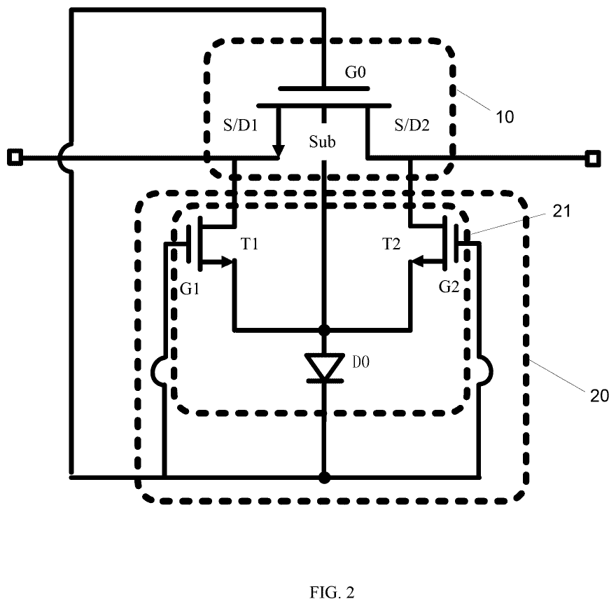

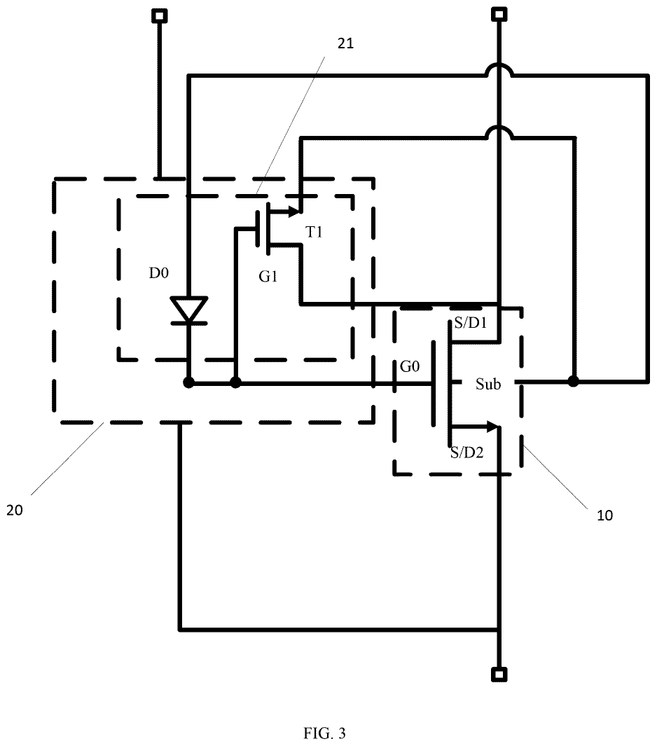

Referring now to FIGS. 2 and 3, potential modulation circuit 20 can include switching module 21. A first end of switching module 21 can be electrically connected to whichever of power end S/D1 or power end S/D2 has the lower voltage, a second end of switching module 21 can be electrically connected to substrate potential end Sub of bidirectional power device 10, and a control end of switching module 21 can be electrically connected to control end G0 of the bidirectional power device. Switching module 21 can, when bidirectional power device 10 is conducting, connect substrate potential end Sub to whichever of power end S/D1 or power end S/D2 has the lower potential, so that substrate potential end Sub remains at the lower potential of bidirectional power device 10. In the turn-off state of the bidirectional power device, by connecting diode D0 to control end G0, substrate potential end Sub may thereby be maintained at the lower potential of bidirectional power device 10.

For example, power end S/D1 may be one of the source and the drain of the bidirectional power device, and power end S/D2 may be the other one of the source and the drain. In particular embodiments, an input end of switching module 21 can connect to power end S/D1 and power end S/D2 of bidirectional power device 10, and an output end of switching module 21 can connect to substrate potential end Sub of bidirectional power device 10. Switching module 21 can modulate substrate potential end Sub according to the lower potential of power end S/D1 and power end S/D2, such that substrate potential end Sub remains at the lower potential, thereby avoiding the impact of substrate floating on the performance and reliability of bidirectional power device 10.

For example, maintaining substrate potential end Sub at the lower potential of power end S/D1 and power end S/D2 may not only reduce thermal effects caused by parasitic effects, improve thermal stability, reliability, and anti-interference capability, and reduce the impact of external noise on device performance, but can also lower the on-resistance of bidirectional power device 10, improve conduction efficiency, reduce switching losses, increase switching speed, and thereby enhance the overall performance of bidirectional power device 10. Further, by integrating the potential modulation circuit into the driving chip where driving circuit 30 of bidirectional power device 10 is located, potential modulation circuit 20 can be fabricated simultaneously with driving circuit 30, which can reduce manufacturing steps and process complexity, improve production efficiency, substantially eliminate the cost of independently fabricating the potential modulation circuit, and lower the overall manufacturing cost.

When designing the driving chip, the potential modulation circuit of bidirectional power device 10 may be designed as a sub-module to ensure its functionality and performance meet requirements. During manufacturing, unified doping and epitaxial growth processes may be used to fabricate driving circuit 30 and potential modulation circuit 20 simultaneously. Through lithography and etching processes, the structures of potential modulation circuit 20 and driving circuit 30 can be formed on the same chip. During metallization and packaging, the connection points of potential modulation circuit 20 and driving circuit 30 may be metallized and packaged.

While the above describes the overall structure and effect of switching module 21, the following describes specific example structures and principles of switching module 21. In the example of FIG. 2, switching module 21 can include transistors T1 and T2. A first end of transistor T1 can be electrically connected to one of power end S/D1 or power end S/D2 of bidirectional power device 10, a second end of transistor T1 can be electrically connected to substrate potential end Sub of bidirectional power device 10, and a control end G1 of transistor T1 can be electrically connected to control end G0 of the bidirectional power device. A first end of transistor T2 can be electrically connected to the other of power end S/D1 or power end S/D2 of the bidirectional power device, a second end of transistor T2 can be electrically connected to substrate potential end Sub of bidirectional power device 10, and a control end G2 of transistor T2 can be electrically connected to control end G0 of the bidirectional power device.

For example, when the first end of transistor T1 is electrically connected to power end S/D1 of the bidirectional power device, the first end of transistor T2 can be electrically connected to power end S/D2. When bidirectional power device 10 is conducting and the voltage of power end S/D1 is lower than the voltage of power end S/D2, transistor T1 can conduct, connecting power end S/D1 of bidirectional power device 10 to substrate potential end Sub. When the control signal is a conduction signal, bidirectional power device 10 can conduct, and transistors T1 and T2 may also conduct. When the voltage of power end S/D2 is lower than the voltage of power end S/D1, current can flow from power end S/D1 to power end S/D2, and the voltage of substrate potential end Sub may be between the potentials of S/D1 and S/D2.

The voltage difference between power end S/D1 and power end S/D2 of bidirectional power device 10 can be relatively small, so substrate potential end Sub can remain at a lower potential. In one example, when the control signal applied to control end G0 of bidirectional power device 10 is a conduction signal, transistors T1 and T2 can simultaneously respond to the control signal. As such, synchronous control of bidirectional power device 10, transistor T1, and transistor T2 can be achieved, thus simplifying control logic, reducing signal transmission delay, and improving response speed.

Transistors T1 and T2 may be implemented using one of a bipolar junction transistor (BJT), a metal-oxide-semiconductor field-effect transistor (MOSFET), an insulated gate bipolar transistor (IGBT), or a junction field-effect transistor (JFET), and any suitable transistor structure can be employed in certain embodiments.

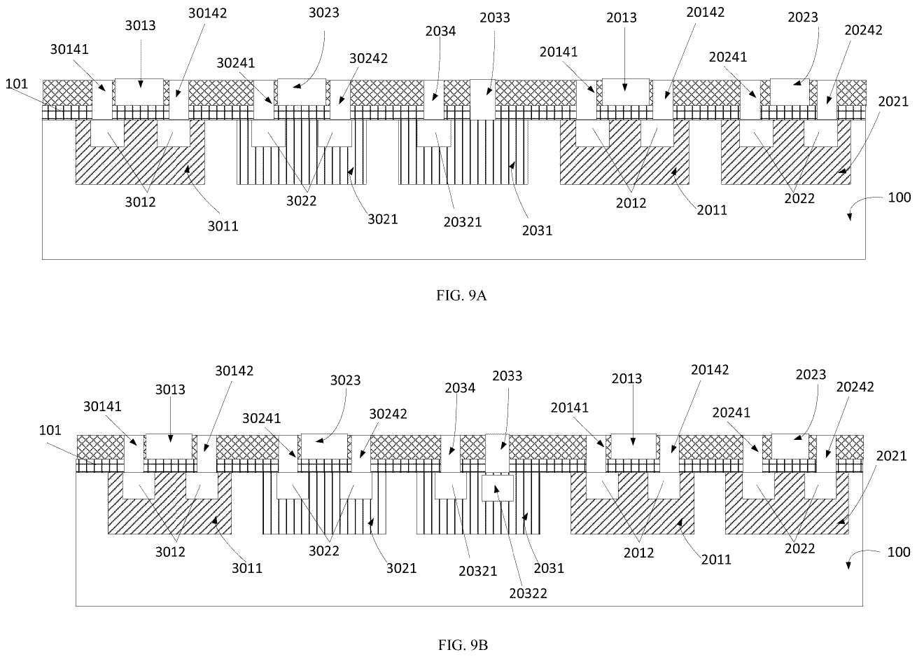

As shown in FIG. 9B, transistor T1 can include well region 2011 of a first doping type located in the substrate, source/drain regions 2012 of a second doping type located in well region 2011, and gate 2013 disposed between source/drain regions 2012. Gate 2013 is the control end of transistor T1, and ends 20141 and 20142 of transistor T1 can be formed on the upper surfaces of source/drain regions 2012. Transistor T2 can include well region 2021 of the first doping type located in the substrate, source/drain regions 2022 of the second doping type located in well region 2021, and gate 2023 disposed on the upper surface of the substrate and between source/drain regions 2022. Gate 2023 may serve as the control end of transistor T2, and ends 20241 and 20242 of transistor T2 can be formed on the upper surfaces of source/drain regions 2022. Control end G1 of transistor T1 and control end G2 of transistor T2 can both connect to control end G0 of bidirectional power device 10.

When a control signal is applied to control end G0 of bidirectional power device 10, transistors T1 and T2 can simultaneously respond to the control signal. As such, synchronous control of bidirectional power device 10, transistor T1, and transistor T2 can be achieved, the control logic can be simplified, the signal transmission delay reduced, and the response speed improved.

For example, when bidirectional power device 10 and transistors T1 and T2 are of the same type of device, the control signal can synchronously control bidirectional power device 10, transistor T1, and transistor T2 to turn on or off. That is, when bidirectional power device 10 is in a conducting state, transistors T1 and T2 can synchronously be in a conducting state. In addition, if the potential of power end S/D1 is lower, current may flow from S/D2 to S/D1, and the substrate potential can be between S/D2 and S/D1, approximately equal to the potential of S/D1. If the potential of power end S/D2 is lower, current may flow from S/D1 to S/D2, and the substrate potential can be between S/D2 and S/D1, approximately equal to the potential of S/D2. When bidirectional power device 10 is in conducting state, the voltage difference between power end S/D1 and power end S/D2 may be relatively small. Therefore, regardless of whether the voltage of power end S/D1 is greater or less than the voltage of power end S/D2, substrate potential end Sub can be maintained at a lower potential.

As shown in FIG. 3, switching module 21 can include transistor T1. A first end of transistor T1 can connect to power end S/D1 of bidirectional power device 10, and a second end of transistor T1 can connect to substrate potential end Sub of bidirectional power device 10. Further, control end G0 of bidirectional power device 10 can connect to control end G1 of transistor T1. When bidirectional power device 10 conducts, the voltage of power end S/D1 can be substantially equal to the voltage of power end S/D2. Since transistor T1 is also conducting, power end S/D1 of bidirectional power device 10 can connect to substrate potential end Sub of bidirectional power device 10 through transistor T1, such that the voltage at substrate potential end Sub equals the voltage at power end S/D1, which is also the voltage at power end S/D2. If there is a voltage difference between S/D1 and S/D2, since bidirectional power device 10 conducts, the voltage difference can be relatively small. Therefore, whether transistor T1 connects to power end S/D1 or to power end S/D2, the substrate potential may remain at a lower potential.

When bidirectional power device 10 is in a turn-off state, substrate potential end Sub can connect through a diode to control end G0 of bidirectional power device 10. When bidirectional power device 10 is in a turn-off state, the voltage at control end G0 can be zero or a negative voltage. Therefore, substrate potential end Sub may equal zero or a negative voltage, ensuring that substrate potential end Sub remains at a lower potential. As such, substrate potential end Sub of bidirectional power device 10 can be maintained at the lower potential among the voltages at control end G0, power end S/D1, and power end S/D2. Since control end G1 of transistor T1 can connect to control end G0 of bidirectional power device 10, when a control signal is applied to control end G0, transistor T1 may simultaneously respond to the control signal. As such, synchronous control of bidirectional power device 10 and transistor T1 can be achieved, simplifying control logic, reducing signal transmission delay, and improving response speed. In this way, substrate potential end Sub of bidirectional power device 10 can be maintained at a lower potential, thereby achieving control of substrate potential end Sub without increasing the cost or parasitic parameters of bidirectional power device 10 itself.

As shown in FIG. 2, the switching module can also include a diode D0. The cathode of diode D0 can be electrically connected to the control end of transistor T1 and the control end of transistor T2, and the anode of diode D0 may be electrically connected to substrate potential end Sub of the bidirectional power device. As shown in FIG. 3, the switching module can also include diode D0. The cathode of diode D0 can be electrically connected to the control end of transistor T1, and the anode of diode D0 can be electrically connected to substrate potential end Sub of the bidirectional power device. When the control signal is a turn-off signal, transistors T1 and T2 may be in an off state, and the voltage at substrate potential end Sub is coupled through diode D0 to the control signal. Since the potential of the control signal is low, substrate potential end Sub of bidirectional power device 10 can be maintained at a lower potential. For example, the diode may be a PN junction diode or a Schottky diode, or any other component having similar functionality in certain embodiments.

As shown in FIG. 1, driving circuit 30 can include transistors T3 and T4. A second end of transistor T3 can be electrically connected to a first end of transistor T4, and may also be electrically connected to substrate potential end Sub and control end G0 of bidirectional power device 10, in order to drive bidirectional power device 10. A control end of transistor T3 can be electrically connected to a control end of transistor T4. The second end (source or drain) of transistor T3 can be electrically connected to the first end (drain or source) of transistor T4, thereby forming an output path to drive the bidirectional power device. The control end of transistor T3 can be electrically connected to the control end of transistor T4, which may indicate that the control end of transistor T3 and the control end of transistor T4 can be synchronously controlled (e.g., they will turn-on or turn-off simultaneously). This synchronous control can ensure the stability and reliability of the driving circuit, and as such, particular embodiments can control the turn-on or turn-off state of the bidirectional power device through the driving circuit.

In particular embodiments, a bidirectional power apparatus can include a driving chip and a bidirectional power device. The driving chip can drive the bidirectional power device and modulate a substrate potential of the bidirectional power device. The driving chip can control the bidirectional power device to be conducting or non-conducting, and to modulate the substrate potential of the bidirectional power device when the bidirectional power device is conducting or non-conducting, such that the voltage at the substrate potential end of the bidirectional power device is substantially consistent with a lowest voltage among the voltages at the control end, the first power end, and the second power end, thereby avoiding the impact of substrate floating on the performance and reliability of the bidirectional power device. The beneficial effects of the bidirectional power apparatus provided in certain embodiments are the same as those of the driving chip described in the examples shown in FIGS. 1-3.

Particular embodiments also provide a method of manufacturing a driving chip. Referring now to FIG. 4, the method can include providing substrate 100 (e.g., a silicon substrate). The substrate may serve as the foundation of the driving chip, carrying the structure of the driving chip. The substrate can provide the planar or three-dimensional structure required for manufacturing the driving chip, thus enabling other functional layers (e.g., epitaxial layers and doped regions) to be orderly formed in or grown on the substrate.

Referring to FIGS. 5 to 9B, the method can also include forming driving circuit 30 and substrate potential modulation circuit 20 in substrate 100. The driving circuit can drive a bidirectional power device, and the substrate potential modulation circuit can modulate a substrate potential of the bidirectional power device. The bidirectional power device can include a first power end, a second power end, a control end, and a substrate potential end. The substrate potential modulation circuit can receive signals from the control end and from the first power end and/or the second power end, and can connect to the substrate potential end, such that the voltage at the substrate potential end of the bidirectional power device is substantially consistent with a lowest voltage among the voltages at the control end, the first power end, and the second power end.

In particular embodiments, the driving chip can include the driving circuit and the substrate potential modulation circuit integrated in the same chip. The substrate potential modulation circuit can receive signals from the control end, the first power end and/or the second power end of the bidirectional power device, and can connect to the substrate potential end of the bidirectional power device, such that the voltage at the substrate potential end is substantially consistent with the lowest voltage among the voltages at the control end, the first power end, and the second power end, thereby avoiding the impact of substrate floating on the performance and reliability of the bidirectional power device.

In particular embodiments, the substrate potential modulation circuit and the driving circuit can be integrated in the driving chip. This may not only avoid increasing the cost and parasitic parameters of the bidirectional power device, but may also allow the potential modulation circuit to be designed according to particular requirements, thereby better achieving management of the substrate potential of the bidirectional power device. Further, by integrating the substrate potential modulation circuit and the driving circuit of the bidirectional power device into the same chip, the substrate potential modulation circuit can be fabricated simultaneously with the driving circuit, may reduce manufacturing steps, improve production efficiency, and thus substantially eliminate the cost of independently fabricating the potential modulation circuit, thereby lowering the overall manufacturing cost of the power conversion apparatus. In some embodiments, the substrate potential modulation circuit can include transistor T1 and/or transistor T2, and the driving circuit can include transistors T3 and T4.

As shown in FIG. 5, forming the driving circuit and the substrate potential modulation circuit in the substrate can include forming well region 2011 and/or well region 2021, and forming well regions 3011 and 3021 in substrate 100. In this way, manufacturing steps of the driving chip can be reduced, thereby improving production efficiency, lowering manufacturing cost, and shortening the production cycle. For example, well regions 2011 and 2021 can include dopant ions of the same type, and well regions 3011 and 3021 can include dopant ions of opposite types. In some examples, well regions 2011, 2021, and 3011 can include dopant ions of the same type, and may be formed simultaneously, thereby reducing process steps and improving manufacturing efficiency. In this way, transistors T1, T2, T3, and T4 having different functions and characteristics can be realized on the same driving chip, thereby meeting application requirements of the driving chip.

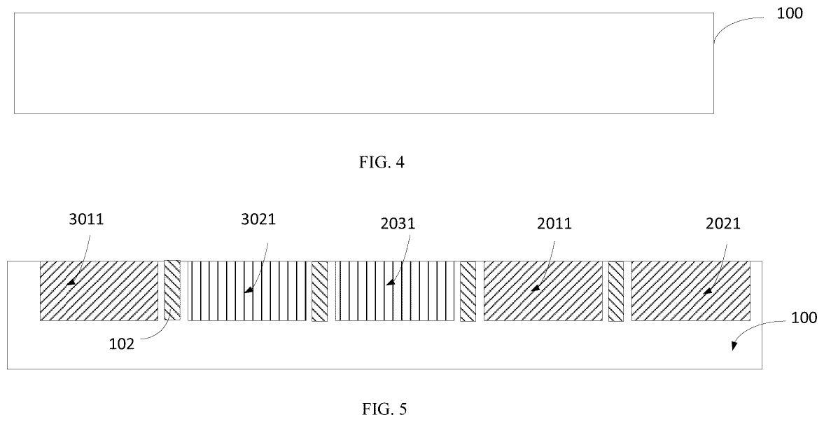

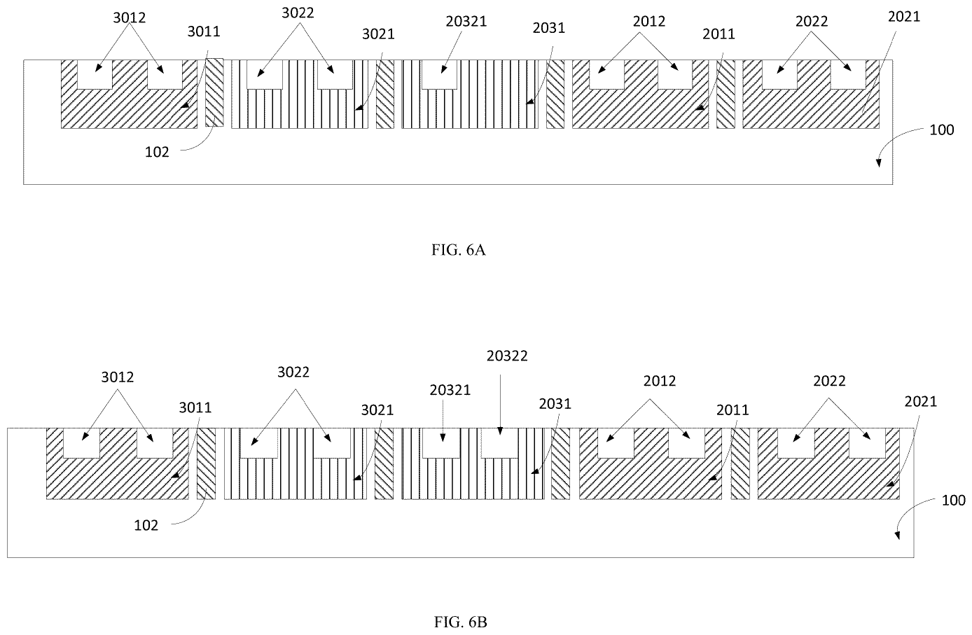

Referring to FIGS. 6A and 6B, the method can include respectively and simultaneously forming source/drain regions 2012 in well region 2011 and/or source/drain regions 2022 in well region 2021, source/drain regions 3012 in well region 3011, and source/drain regions 3022 in well region 3021. Source/drain regions 2012 and well region 2011 may include dopant ions of opposite types, and source/drain regions 2022 and well region 2021 may include dopant ions of opposite types. Source/drain regions 3012 and well region 3011 can include dopant ions of opposite types. Also, source/drain regions 3022 and well region 3021 may include dopant ions of opposite types. As such, corresponding source/drain regions can be simultaneously formed in different well regions, thereby improving manufacturing efficiency.

For example, forming source/drain regions 2012 in well region 2011 and forming source/drain regions 2022 in well region 2021 can enable realization of transistors of the same type (e.g., multiple NMOS or PMOS transistors) on the same driving chip. For example, forming source/drain regions 3012 in well region 3011 and forming source/drain regions 3022 in well region 3021 can enable realization of transistors of different types (such as NMOS and PMOS) on the same driving chip. The respective well regions can provide electrical isolation between different transistors, thereby reducing interference among the transistors.

For example, the substrate potential modulation circuit can also include a diode. As shown in FIG. 5, the method can also include forming well region 2031 in the substrate. The dopant ion type of well region 2031 can be the same as that of well region 3021. As such, well region 2031 can be formed in the substrate simultaneously with the formation of the fourth well region, thereby reducing process steps in manufacturing the driving chip and improving process efficiency. Any suitable formation sequence of well regions 2011, 2021, 3011, 3021, and 2031 can be supported in certain embodiments.

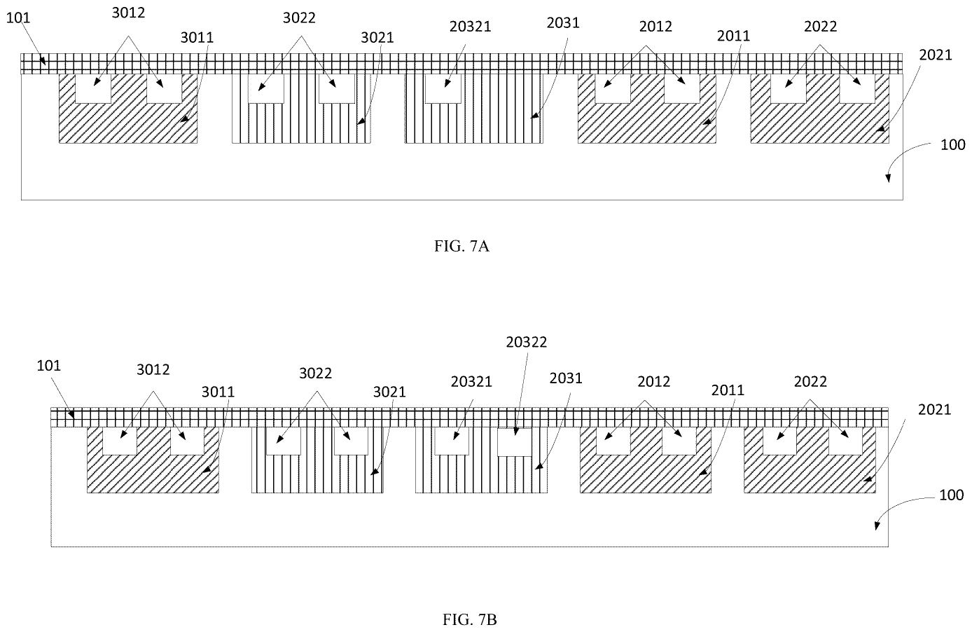

Referring to FIGS. 6A and 6B, while respectively and simultaneously forming the first source/drain regions in the first well region 2011, the second source/drain regions in well region 2021, the third source/drain regions in well region 3011, and the fourth source/drain regions in well region 3021, the method can also include forming doped region 20321 and/or doped region 20322 in well region 2031. In particular embodiments, by forming doped region 20321 and/or doped region 20322 in the fifth well region, the chip area can be better utilized, achieving higher integration and performance. In some examples, doped regions 20321 and 20322 can be used as functional regions for subsequently forming a diode. The dopant ion types of doped regions 20321 and 20322 may be opposite. As such, when two adjacent regions have opposite doping types (one n-type and the other p-type), a PN junction is formed between them. This PN junction can form a PN junction diode, e.g., between doped region 20321 and doped region 20322, as shown in FIGS. 6B and 7B.

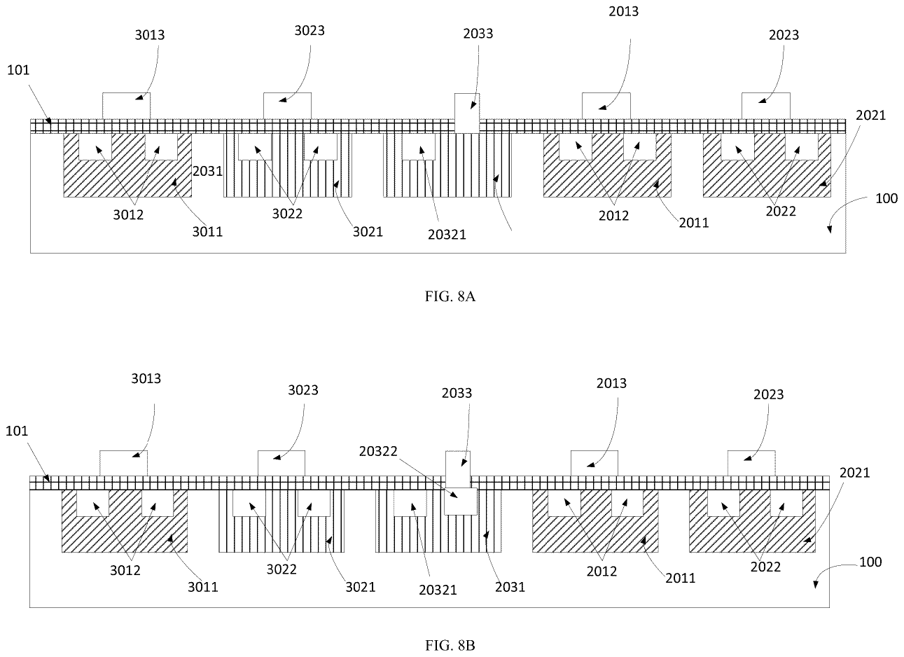

Referring now to FIGS. 8A and 8B, the method can also include respectively and simultaneously forming gate 2013 and/or gate 2023, gate 3013, and gate 3023 on the upper surface of substrate 100. Gate 2013 may serve as the control end of transistor T1, gate 2023 may serve as the control end of transistor T2, gate 3013 may serve as the control end of transistor T3, and gate 3023 may serve as the control end of transistor T4. By completing the formation of multiple gates in the same process step, the number of process steps can be reduced, thereby lowering cost and shortening production time. Moreover, by forming multiple gates on the same substrate, multiple circuit functions and application requirements can be supported.

In some examples, as shown in FIGS. 7A and 7B, after the above step, the manufacturing method may also include forming dielectric layer 101 on the upper surface of substrate 100. In particular embodiments, the dielectric material of dielectric layer 101 can include silicon dioxide (SiO₂), silicon nitride (Si₃N₄), or other low-dielectric-constant materials. The choice of material depends on the particular required electrical, mechanical, and thermal properties. For example, dielectric layer 101 can be used to isolate the source/drain regions and the corresponding gates.

As shown in FIGS. 8A and 8B, the method can include respectively and simultaneously forming gate 2013 and/or gate 2023, gate 3013, and gate 3023 on the upper surface of dielectric layer 101. Dielectric layer 101 can help reduce interference and crosstalk between different gates and source/drain regions, thereby ensuring signal integrity.

Referring to FIGS. 9A and 9B, the method can also include respectively and simultaneously forming, on the upper surfaces of the first source/drain regions and/or the second source/drain regions, the third source/drain regions, and the fourth source/drain regions, first metal electrodes (20141 and 20142), second metal electrodes (20241 and 20242), third metal electrodes (30141 and 30142), and fourth metal electrodes (30241 and 30242) penetrating the dielectric layer. The first metal electrodes (20141 and 20142) can be located on two sides of gate 2013 and electrically connected to source/drain regions 2012, and/or the second metal electrodes (20241 and 20242) are located on two sides of gate 2023 and electrically connected to source/drain regions 2022, and the third metal electrodes (30141 and 30142) are located on two sides of gate 3013 and electrically connected to source/drain regions 3012, and the fourth metal electrodes (30241 and 30242) are located on two sides of gate 3023 and electrically connected to source/drain regions 3022.

For example, the above metal electrodes may provide electrical connection between the corresponding source/drain regions and external circuits. By forming metal electrodes penetrating the dielectric layer, current can be effectively transmitted from the source/drain regions to external circuits. For example, while performing the above step, the manufacturing method can also include forming, on the upper surface of well region 2031, an anode metal electrode (one of 2033 and 2034) and a cathode metal electrode (the other of 2033 and 2034) penetrating the dielectric layer.

As shown in FIG. 9B, the cathode metal electrode can be formed on the upper surface of doped region 20321 and electrically connected to doped region 20321, and/or the anode metal electrode may be formed on the upper surface of doped region 20322 and electrically connected to doped region 20322, thereby forming a PN diode. As shown in FIG. 9A, doped region 20321 can contact cathode metal electrode 2034, and anode metal electrode 2033 can contact the upper surface of well region 2031, thereby forming a Schottky diode. In particular embodiments, the anode and cathode metal electrodes may provide electrical connection to external circuits. By forming anode and cathode metal electrodes penetrating the dielectric layer, current can be effectively transmitted from the first and second doped regions to external circuits. Moreover, the above operation can reduce the number of process steps, thereby potentially reducing costs and shortening production time.

In some examples, as shown in FIG. 5, after forming the first well region and/or the second well region in the substrate, and forming the third well region and the fourth well region in the substrate, the method can also include simultaneously forming isolation regions 102 between two adjacent well regions among well region 2011 and/or well region 2021, well region 3011, and well region 3021. As such, isolation regions 102 can be used to prevent current leakage between adjacent well regions, thus ensuring that devices within each well region can operate independently without being affected by adjacent regions.

The isolation regions may be implemented by shallow trench isolation (STI) or deep trench isolation (DTI) technology. Through the above steps, the manufacturing of the driving chip can be achieved, and thereafter the functional regions may be electrically connected in the following manner. One of the first metal electrodes on the source or drain of the first source/drain regions can be grounded and electrically connected to one of the first power end and the second power end of the bidirectional power device. The other one of the first metal electrodes can connect to the anode metal electrode on the fifth well region and further connected to the substrate potential end of the bidirectional power device.

One of the second metal electrodes on the source or drain of the second source/drain regions can be electrically connected to the other of the first power end and the second power end of the bidirectional power device. The other one of the second metal electrodes can connect to the anode metal electrode on the fifth well region and further connected to the substrate potential end of the bidirectional power device. The first gate and the second gate can be electrically connected together and connected to the control end of the bidirectional power device. The control end of the bidirectional power device may further be electrically connected to the cathode metal electrode on the fifth well region. The third metal electrodes on the third source/drain regions can connect to the cathode metal electrode on the fifth well region. The fourth metal electrodes on the fourth source/drain regions can connect to the cathode metal electrode on the fifth well region. The third gate and the fourth gate can be electrically connected together and connected to the same control voltage end.

The cathode metal electrode on the fifth well region can be electrically connected to the control end of the bidirectional power device. The anode metal electrode on the fifth well region can be electrically connected to the substrate potential end of the bidirectional power device. In this way, an example method for manufacturing the driving chip is provided. The driving circuit of the bidirectional power device and the substrate potential modulation circuit can be integrated in the same chip. By fabricating the substrate potential modulation circuit simultaneously with the driving circuit, manufacturing steps can be reduced, thereby improving production efficiency, eliminating the cost of independently fabricating the potential modulation circuit, and further lowering the overall manufacturing cost of the power conversion apparatus.

Particular embodiments may also provide a method for manufacturing a bidirectional power apparatus, which can include the driving chip as described above and a bidirectional power device. The method can include providing substrates 100 and 200. For example, substrate 100 of the driving chip can be a silicon (Si) substrate, and substrate 200 may be a Si substrate, a sapphire substrate, a SiC substrate, or the like.

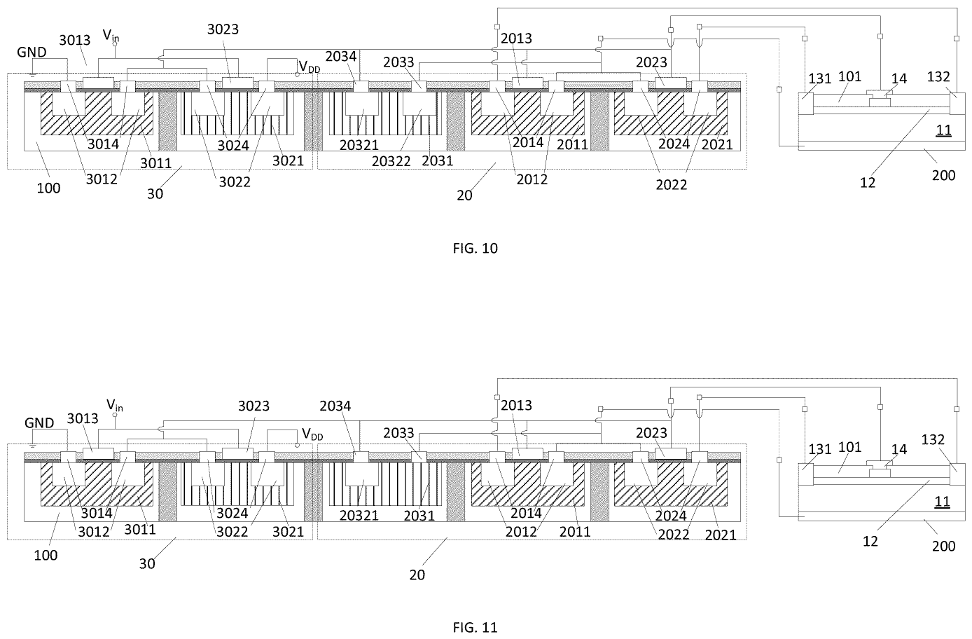

Referring now to FIG. 10, the driving chip can be fabricated on substrate 100, and simultaneously the bidirectional power device may be fabricated on substrate 200. The step of fabricating the bidirectional power device on substrate 200 may include forming buffer layer 11 (e.g., GaN layer) on substrate 200, forming barrier layer 12 (e.g., AlGaN) on buffer layer 11, and forming dielectric layer 101 on an upper surface of barrier layer 12.

For example, after forming the dielectric layer on the upper surface of substrate 200, the method can also include forming metal electrode 131, metal electrode 132, and control electrode 14. Metal electrode 131 may serve as the first power end of the bidirectional power device, metal electrode 132 may serve as the second power end of the bidirectional power device, and the control electrode serves as the control end of the bidirectional power device. As such, the manufacturing of the bidirectional power apparatus can be achieved, and thereafter the bidirectional power device and the driving chip may be electrically connected in the following manner.

Referring to FIGS. 10 and 11, one of metal electrodes 3014 on source/drain regions 3012 can be grounded, and the other can be electrically connected to one of metal electrodes 3024 on source/drain regions 3022 and to control electrode 14 of the bidirectional power device. The other one of metal electrodes 3024 on source/drain regions 3022 can connect to a voltage terminal VDD. The third and fourth gates can be electrically connected together and connected to the same control voltage terminal Vin.

One of metal electrodes 2014 on source/drain regions 2012 can be electrically connected to the second power end of the bidirectional power device, and the other is electrically connected to one of metal electrodes 2024 can also connect to substrate 200 of the bidirectional power device. The other one of metal electrodes 2024 can connect to the first power end of the bidirectional power device. Gates 2013 and 2023 can be electrically connected to control electrode 14 of the bidirectional power device. Anode metal electrode 2033 may be electrically connected to substrate 200 of the bidirectional power device, and cathode metal electrode 2034 can be electrically connected to control electrode 14 of the bidirectional power device.

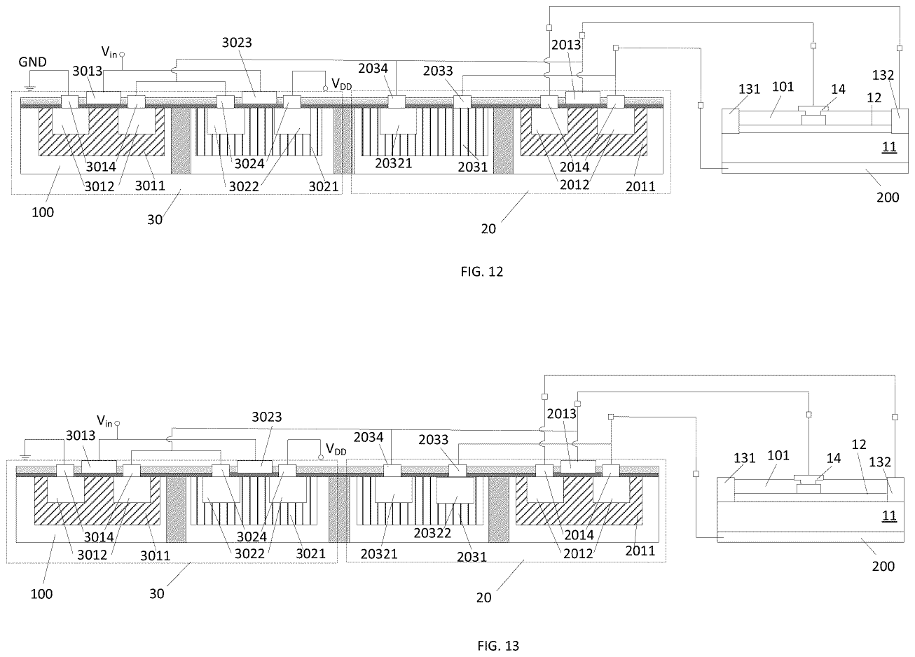

Referring to FIGS. 12 and 13, one of metal electrodes 3014 on source/drain regions 3012 can be grounded, and the other may be electrically connected to one of metal electrodes 3024 on source/drain regions 3022 and to control electrode 14 of the bidirectional power device. The other one of metal electrodes 3024 on source/drain regions 3022 can connect to voltage terminal VDD. The third and fourth gates can be electrically connected together and connected to the same control voltage terminal Vin.

One of metal electrodes 2014 on source/drain regions 2012 can be electrically connected to the second power end of the bidirectional power device, and the other may be electrically connected to substrate 200 of the bidirectional power device. Gate 2013 can be electrically connected to control electrode 14 of the bidirectional power device. Anode metal electrode 2033 can be electrically connected to substrate 200 of the bidirectional power device, and cathode metal electrode 2034 may be electrically connected to control electrode 14 of the bidirectional power device.

Thus, in particular embodiments, the driving chip may be fabricated on the first substrate, and simultaneously the bidirectional power device is fabricated on the second substrate. This can enable an efficient production process while ensuring that the performance and reliability of the driving chip and the bidirectional power device meet application requirements.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A driving chip for driving a bidirectional power device and modulating a substrate potential of the bidirectional power device, the bidirectional power device comprising a first power end, a second power end, a control end, and a substrate potential end, comprising:
a driving circuit, and
a substrate potential modulation circuit;
wherein the driving circuit and the substrate potential modulation circuit are formed on a same substrate;
wherein the substrate potential modulation circuit is configured to receive signals from the control end and from the first power end and/or the second power end, and is coupled to the substrate potential end, such that a voltage at the substrate potential end of the bidirectional power device is substantially consistent with a lowest voltage among voltages at the control end, the first power end, and the second power end.

2. The driving chip according to claim 1, wherein the substrate potential modulation circuit comprises a switching module, a first end of the switching module is electrically coupled to whichever of the first power end of the second power end has the lower voltage, a second end of the switching module is electrically coupled to the substrate potential end of the bidirectional power device, and a control end of the switching module is electrically coupled to the control end of the bidirectional power device.

3. The driving chip according to claim 2, wherein the switching module comprises a first transistor, a first end of the first transistor is electrically coupled to one of the first power end and the second power end of the bidirectional power device, a second end of the first transistor is electrically coupled to the substrate potential end of the bidirectional power device, and a control end of the first transistor is electrically coupled to the control end of the bidirectional power device.

4. The driving chip according to claim 3, wherein the first transistor comprises a first well region of a first doping type that is located in the substrate, first source/drain regions of a second doping type that are located in the first well region, and a first gate that is disposed between the first source/drain regions; wherein the first gate is the control end of the first transistor.

5. The driving chip according to claim 3, wherein the switching module further comprises a second transistor, a first end of the second transistor is electrically coupled to the other one of the first power end and the second power end of the bidirectional power device, a second end of the second transistor is electrically coupled to the substrate potential end of the bidirectional power device, and a control end of the second transistor is electrically coupled to the control end of the bidirectional power device.

6. The driving chip according to claim 5, wherein the second transistor comprises a second well region of a first doping type that is located in the substrate, second source/drain regions of a second doping type that are located in the second well region, and a second gate that is disposed on an upper surface of the substrate and between the second source/drain regions; wherein the second gate is the control end of the second transistor.

7. The driving chip according to claim 5, wherein the switching module further comprises a diode, a cathode of the diode is electrically coupled to the control end of the first transistor and/or the control end of the second transistor, and an anode of the diode is electrically coupled to the substrate potential end of the bidirectional power device.

8. The driving chip according to claim 7, wherein the diode is configured as a PN junction diode or a Schottky diode.

9. The driving chip according to claim 1, wherein the driving circuit comprises a third transistor and a fourth transistor,
wherein a second end of the third transistor is electrically coupled to a first end of the fourth transistor, and is further electrically coupled to the substrate potential end and the control end of the bidirectional power device, so as to drive the bidirectional power device;
wherein a control end of the third transistor is electrically connected to a control end of the fourth transistor.

10. A bidirectional power apparatus, comprising a bidirectional power device, and a driving chip according to any one of claims 1 to 9, wherein the driving chip is configured to drive the bidirectional power device and to modulate the substrate potential of the bidirectional power device.

11. A method for manufacturing a driving chip, comprising:
providing a substrate; and
forming a driving circuit and a substrate potential modulation circuit in the substrate, wherein the driving circuit is configured to drive a bidirectional power device, and the substrate potential modulation circuit is configured to modulate a substrate potential of the bidirectional power device;
wherein the bidirectional power device comprises a first power end, a second power end, a control end, and a substrate potential end;
wherein the substrate potential modulation circuit is configured to receive signals from the control end and from the first power end and/or the second power end, and is connected to the substrate potential end, such that the substrate potential end of the bidirectional power device is substantially consistent with a lowest voltage among voltages at the control end, the first power end and the second power end.

12. The method according to claim 11, wherein the substrate potential modulation circuit comprises a first transistor and/or a second transistor, and the driving circuit comprises a third transistor and a fourth transistor;
wherein forming the driving circuit and the substrate potential modulation circuit in the substrate comprises:
simultaneously forming first source/drain regions and/or second source/drain regions, third source/drain regions, and fourth source/drain regions in the substrate, wherein the first source/drain regions are a first end and a second end of the first transistor, the second source/drain regions are a first end and a second end of the second transistor, the third source/drain regions are a first end and a second end of the third transistor, and the fourth source/drain regions are a first end and a second end of the fourth transistor; and
simultaneously forming a first gate and/or a second gate, a third gate, and a fourth gate on an upper surface of the substrate, wherein the first gate is a control end of the first transistor, the second gate is a control end of the second transistor, the third gate is a control end of the third transistor, and the fourth gate is a control end of the fourth transistor.

13. The method according to claim 12, wherein simultaneously forming the first source/drain regions and/or the second source/drain regions, the third source/drain regions, and the fourth source/drain regions in the substrate comprises:
forming a first well region and/or a second well region, a third well region, and a fourth well region in the substrate; and
simultaneously forming the first source/drain regions in the first well region and/or the second source/drain regions in the second well region, the third source/drain regions in the third well region, and the fourth source/drain regions in the fourth well region.

14. The method according to claim 13, wherein the first well region and the second well region have a same dopant ion type;
wherein the third well region and the fourth well region have opposite dopant ion types;
wherein the first source/drain regions and the first well region have opposite dopant ion types;
wherein the second source/drain regions and the second well region have opposite dopant ion types;
wherein the third source/drain regions and the third well region have opposite dopant ion types;
wherein the fourth source/drain regions and the fourth well region have opposite dopant ion types.

15. The method according to claim 14, wherein the substrate potential modulation circuit further comprises a diode;
wherein when forming the first well region and/or the second well region, the third well region, and the fourth well region in the substrate, the method comprises:
simultaneously forming a fifth well region in the substrate;
wherein when forming the first source/drain regions in the first well region and/or the second source/drain regions in the second well region, forming the third source/drain regions in the third well region, and forming the fourth source/drain regions in the fourth well region, the method comprises:
simultaneously forming a first doped region and/or a second doped region in the fifth well region.

16. The method according to claim 15, wherein the fifth well region has a dopant ion type opposite to that of the first well region and the second well region;
wherein the first doped region and the second doped region have opposite dopant ion types.

17. The method according to claim 15 or claim 16, wherein after simultaneously forming the first source/drain regions in the first well region and/or the second source/drain regions in the second well region, the third source/drain regions in the third well region, and the fourth source/drain regions in the fourth well region, the method further comprises:
forming a dielectric layer on the upper surface of the substrate.

18. The method according to claim 17, wherein simultaneously forming the first gate and/or the second gate, the third gate, and the fourth gate on the upper surface of the substrate comprises:
simultaneously forming the first gate and/or the second gate, the third gate, and the fourth gate on an upper surface of the dielectric layer.

19. The method according to claim 18, further comprising:
respectively and simultaneously forming, on upper surfaces of the first source/drain regions and/or the second source/drain regions, the third source/drain regions, and the fourth source/drain regions, first metal electrodes and/or second metal electrodes, third metal electrodes, and fourth metal electrodes penetrating the dielectric layer;
wherein the first metal electrodes are located on two sides of the first gate and are electrically connected to the first source/drain regions and/or the second metal electrodes are located on two sides of the second gate and are electrically connected to the second source/drain regions; the third metal electrodes are located on two sides of the third gate and are electrically connected to the third source/drain regions; and the fourth metal electrodes are located on two sides of the fourth gate and are electrically connected to the fourth source/drain regions.

20. The method according to claim 19, wherein when respectively and simultaneously forming, on upper surfaces of the first source/drain regions and/or the second source/drain regions, the third source/drain regions, and the fourth source/drain regions, first metal electrodes and/or second metal electrodes, third metal electrodes, and fourth metal electrodes penetrating the dielectric layer, the method comprises:
simultaneously forming an anode metal electrode and a cathode metal electrode that penetrate the dielectric layer on an upper surface of the fifth well region;
wherein the anode metal electrode is formed on an upper surface of the first doped region and is electrically connected to the fifth well region; and/or the cathode metal electrode is formed on an upper surface of the second doped region and is electrically connected to the fifth well region.

21. The method according to any one of claims 13 to 16, wherein after simultaneously forming the first well region and/or the second well region in the substrate and simultaneously forming the third well region and the fourth well region in the substrate, the method further comprises:
simultaneously forming an isolation region between two adjacent well regions among the first well region and/or the second well region, the third well region, and the fourth well region.

22. A method for manufacturing a bidirectional power apparatus, wherein the bidirectional power apparatus comprises a bidirectional power device and a driving chip according to any one of claims 1 to 9;
wherein the method comprises:
providing a first substrate and a second substrate; and
fabricating the driving chip on the first substrate, and simultaneously fabricating the bidirectional power device on the second substrate.
